(19) United States
(12) Patent Application Publication
(10) Pub. No.: US 2009/0127684 A1
(43) Pub. Date: May 21, 2009

(54) LEADFRAME FOR LEADLESS PACKAGE

(75) Inventors: HENG CHANG KUO, TAINAN COUNTY (TW); PO KAI HOU, TAINAN COUNTY (TW); CHUN YING LIN, TAINAN COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: CHIPMOS TECHNOLOGIES INC., HSINCHU (TW)

(21) Appl. No.: 12/262,580

(22) Filed: Oct. 31, 2008

(30) Foreign Application Priority Data
Nov. 21, 2007 (TW) 096144010

(51) Int. Cl. H01L 23/495

(52) U.S. Cl. 257/676; 257/E23.031

(57) ABSTRACT

A leadframe for a leadless package comprises a plurality of package areas, a plurality of slots, an insulating layer, and a tape (film). Each package area comprises a plurality of package units, each of which comprises a die pad and a plurality of leads surrounding the die pad. The plurality of slots are disposed around each of the package units. The insulating layer is filled in a plurality of slots between the package areas. The tape (film) fixes the plurality of package areas, the plurality of connection portions, the plurality of die pads, and the plurality of leads in place.

### BACKGROUND OF THE INVENTION

(A) Field of the Invention

The present invention relates to a leadframe for a leadless package, and more particularly, to a leadframe used by a Quad Flat Non-leaded package (QFN).

(B) Description of the Related Art

Current trends of consumer electronics have focused on minimal weight and compact size. Accordingly, the QFN package is currently being applied to the traditional leaded package, and has successfully replaced the more expensive wafer level CSP (chip scale package). The CSP has reduced the size of the package to approximately the size of the chip, but requires fine-pitch tin ball grid arrays acting as terminals of the package so that the difficulty in manufacturing such a precision package is very high. In contrast, the QFN package is not only compact in size, low in cost, and high in yield, but can also provide advantages in coplanarity and cooling performance especially for high-speed and power management circuits. Furthermore, the QFN package does not require any pin leads extending from the sides of its package body, and therefore provides better electrical performance than the traditional package that requires a plurality of leads extending from its sides. For example, the SO (single outline) series lead package or QFP (Quad Flat package) series lead package both require leads at their sides, and, like an antenna, the leads are likely to cause noise interference in high frequency applications.

FIG. 1 is a top view showing the semi-finished product of a conventional QFN package 10. The leadframe 12 comprises a plurality of package areas 11, each of which comprises a plurality of package units 112 arranged as an array. The saw streets 113 and 114 surround the package units 112, and a cutter can pass through these streets to divide the package units 112 into individual components. Meanwhile, the cutter cuts the supporting bars (not shown) connected to the package 111 and leadframe 12.

FIG. 2 is an illustration showing the singulation process of a conventional QFN package. A cutting blade 80 cuts the QFN package 10 along the saw streets 113 and 114 to isolate each of the package units 112, and the edge of the cutting blade 80 is required to cut off the package 111 and leadframe 12 simultaneously. In general, the material of the common packages 111 is a compound of epoxy, silicon particle fillers, and hardener, and the leadframe 12 is made from a metallic alloy. The edge of the cutting blade 80 comprises resin bond and diamond dots thereon, but it cannot have good cutting performance on both the package 111 and the metallic leadframe 12. When cutting through the leadframe 12, the cutting blade 80 experiences more wear. The lifespan of the cutting blade 80 is reduced due to cutting metallic materials, and consequently the frequency of cutting tool replacement increases. If the cutting speed is decreased in order to reduce the wear of the cutting blade 80, then the units per hour (UPH) of the cutting process is reduced so that the advantage of mass production is lessened. Clearly, the conventional QFN package still has aforesaid existing problems that remain unresolved.

### SUMMARY OF THE INVENTION

One aspect of the present invention provides a leadframe for a leadless package, wherein a plurality of gaps or slots surrounding each of the package units act as sawing streets for a singulation process, thereby reducing the wear of the cutting tools and improving cutting efficiency.

Another aspect of the present invention provides a leadframe with superior structural rigidity for a leadless package. An insulating material is filled in a plurality of slots between package areas of the leadframe, or even is filled in gaps between a die pad and a plurality of leads of each package area. Therefore, the structural integrity of the leadframe is improved. When the leadframe is picked and placed, it can be effectively transferred without risk of damage.

In view of the above aspects, the present invention provides a leadframe for a leadless package. The leadframe comprises a plurality of package areas, a plurality of slots, an insulating layer, and a tape (film). Each package area comprises a plurality of package units, each of which comprises a die pad and a plurality of leads surrounding the die pad. The plurality of slots are disposed around each of the package units. The insulating layer is filled in a plurality of slots between the package areas. The tape (film) fixes the plurality of package areas, the plurality of connection portions, the plurality of die pads, and the plurality of leads in place.

The present invention further provides a leadless package. The leadless package comprises a die pad, a plurality of leads, an insulating layer, at least one die and an encapsulation body. The plurality of leads surround the die pad. The plurality of slots are disposed around each of the package units. The insulating layer is filled in gaps surrounding the die pad and the plurality of leads. The thickness of the insulating layer is smaller than the thickness of the lead. The die is mounted on the die pad, and is electrically connected to the plurality of leads. The encapsulation body is overlaid on the die, die pad, and the plurality of leads.

### BRIEF DESCRIPTION OF THE DRAWINGS

The objectives and advantages of the present invention will become apparent upon reference to the following description and the accompanying drawings in which:

FIG. 1 is a top view showing the semi-finished product of a conventional QFN package;

FIG. 2 is an illustration showing the singulation process of a conventional QFN package;

FIG. 3A is a top view showing a leadframe for a leadless package in accordance with one embodiment of the present invention;

FIG. 3B is a cross-sectional illustration along the line A-A in FIG. 3A;

FIG. 4A is a top view showing a leadframe for a leadless package in accordance with another embodiment of the present invention;

FIG. 4B is a cross-sectional illustration along the line B-B in FIG. 4A;

FIG. 4C is a cross-sectional illustration of a leadframe in accordance with yet another embodiment of the present invention;

FIG. 4D is a cross-sectional illustration along the line C-C in FIG. 4A;

FIG. 4E is a cross-sectional illustration of a leadframe in accordance with another embodiment of the present invention; and

FIG. 5 is a schematic cross-sectional illustration of a leadless package in accordance with an embodiment of the present invention.

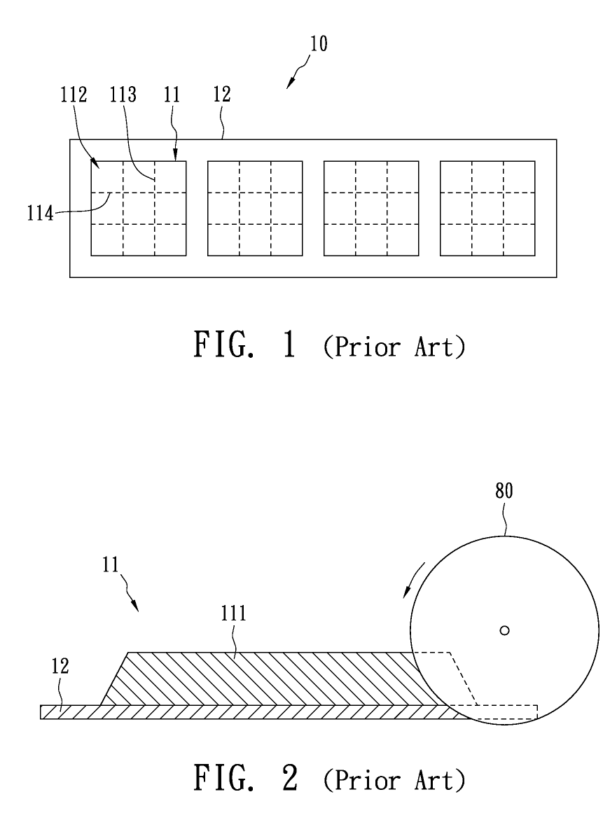

### DETAILED DESCRIPTION OF THE INVENTION

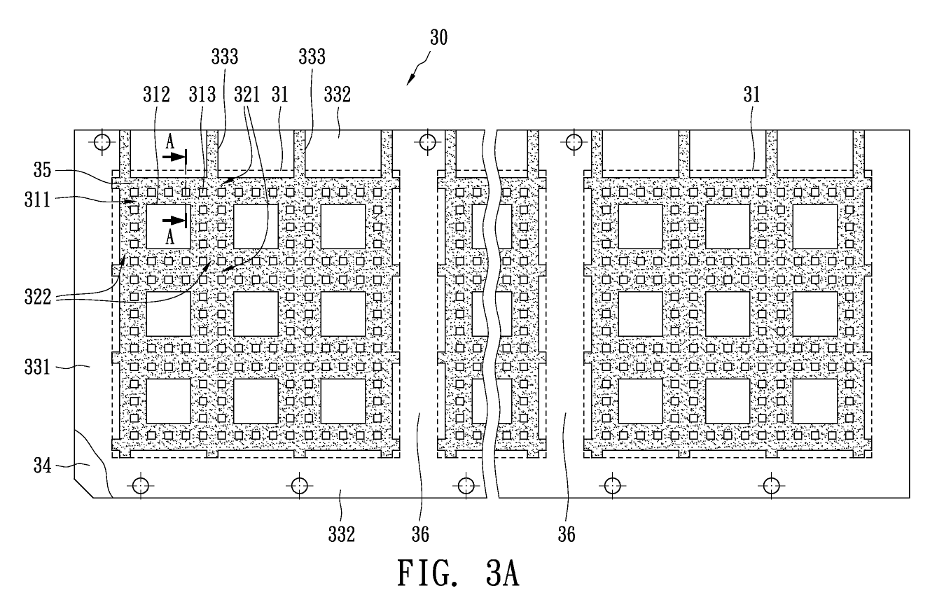

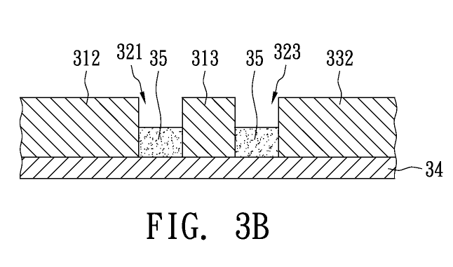

FIG. 3A is a top view showing a leadframe for a leadless package in accordance with one embodiment of the present invention. A leadframe 30 comprises a plurality of package areas 31, a plurality of slots 321 and 322, an insulating layer 35, a plurality of connection portions 36, and a tape (film) 34. Each of the package areas 31 comprises a plurality of package units 311 arranged in a matrix. Each of the connection portions 36 is set between two adjacent package areas 31. Each of the package units 311 comprises a die pad 312 and a plurality of leads 313. There are gaps around the die pad 312 and the plurality of leads 313. The plurality of slots 321 and 322 surround each of the package units 311. Each of the slots 321 extends along the longitudinal direction (long edge) of the leadframe 30, and is connected to a side rail 331 or one of the connection portions 36. Furthermore, each of the slots 322 extends along the transversal direction (short edge) of the leadframe 30, and is connected to a side rail 332 and one of grooves 333. The insulating layer 35 is filled in the slots 321 and 322 surrounding each of the package units 311. The thickness of the insulating layer 35 is smaller than the thickness of the lead 313. The tape 34 fixes the plurality of package areas 31, the plurality of connection portions 36, the insulating layer 35, the side rails 331, 332, the die pads 312 and the plurality of leads 313 surrounding the die pads 312.

FIG. 3B is a cross-sectional illustration along the line A-A in FIG. 3A. The insulating layer 35 such as epoxy resin is filled in the slots 323 between the die pad 312 and the plurality of leads 313 and the slots 321 surrounding the package units 311. The thickness of the insulating layer 35 is smaller than the thickness of the lead 313.

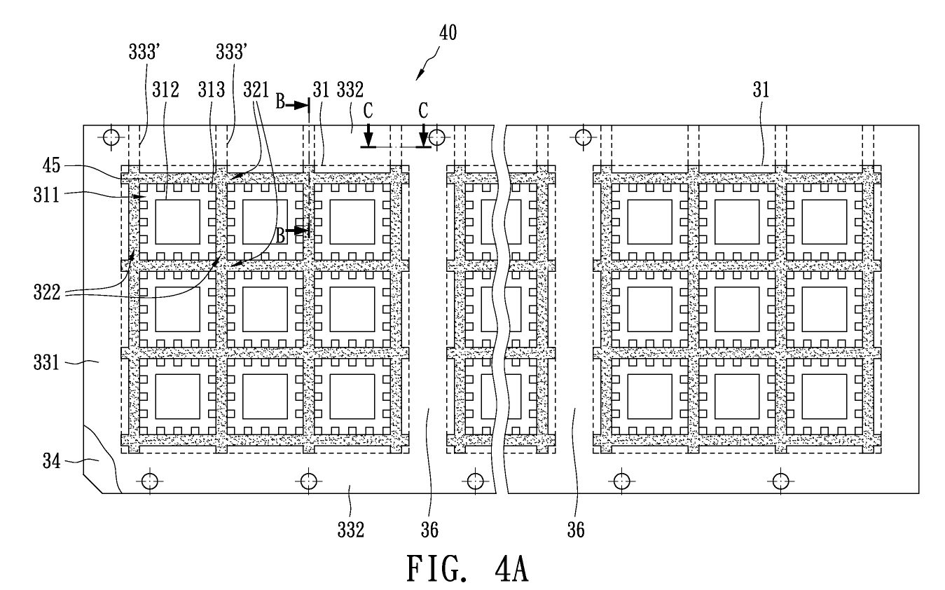

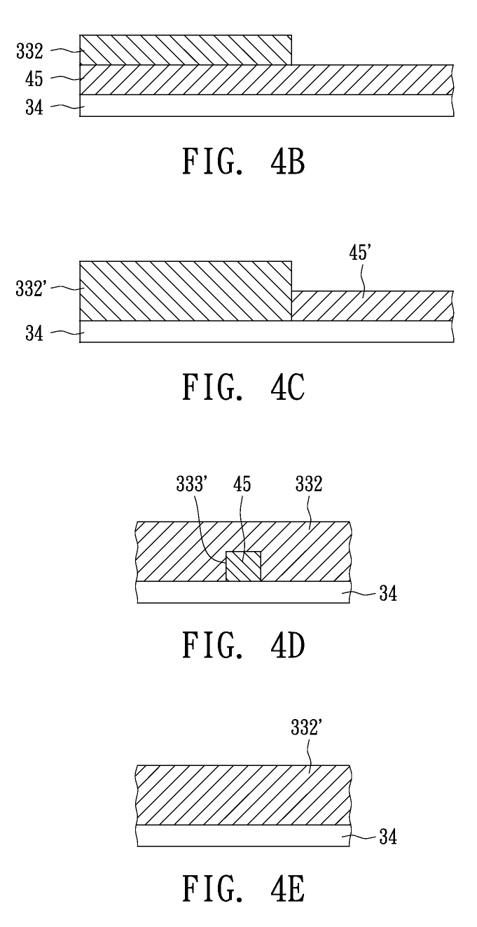

If the top surface of the upper second side rail 332 serves as the bottoms of runners and gates during a molding process, grooves 333′ can be formed on the bottom surface of the second side rail 332, as shown in FIG. 4A. FIG. 4A is a top view showing a leadframe for a leadless package in accordance with another embodiment of the present invention. Compared with FIG. 3, the grooves 333′ are formed on the bottom surface of the side rail 332 through a half-etching process, and are connected to the slots 322.

FIG. 4B is a cross-sectional illustration along the line B-B in FIG. 4A. Unlike those in FIG. 3B, the grooves 333′ in FIG. 4B do not pass through the top and bottom surfaces of the second side rail 332. An insulating layer 45 is still filled in the grooves 333′. Alternatively, the side rail 332′ cannot have grooves, and an insulating layer 45′ is filled in the region of the package unit 311, as shown in FIG. 4C.

FIG. 4D is a cross-sectional illustration along the line C-C in FIG. 4A. The grooves 333 filled with the insulating layer 45 are toward the tape 34, and are covered by the tape 34. FIG. 4E is another cross-sectional illustration of the second side rail 332′ at the same location. The two cross-sectional directions are perpendicular to each other.

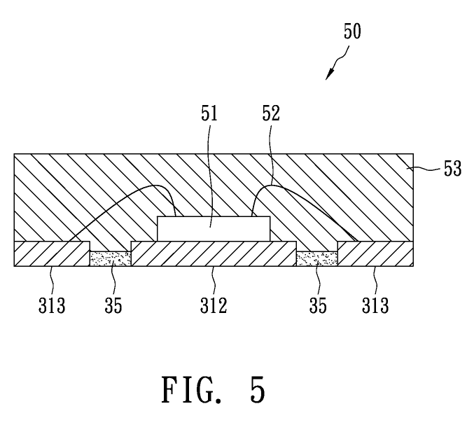

FIG. 5 is a schematic cross-sectional illustration of a leadless package in accordance with an embodiment of the present invention. A leadless package 50 comprises a die pad 312, a plurality of leads 313, an insulation layer 35, at least one die 51 and an encapsulation body 53. The plurality of leads 313 surround the die pad 313, and they are separated from each other. The insulation layer 35 is filled in the gaps around the die pad 312 and the plurality of leads 313. The thickness of the insulating layer 35 is smaller than the thickness of the lead 313. The die 51 is disposed on the die pad 312, and is electrically connected to the plurality of leads 313 through a plurality of metal wires 52. The encapsulation body 53 is overlaid on the die 51, die pad 312, the plurality of metal wires 52 and leads 313.

The above-described embodiments of the present invention are intended to be illustrative only. Numerous alternative embodiments may be devised by those skilled in the art without departing from the scope of the following claims.

What is claimed is:

1. A leadframe for a leadless package, comprising:
a plurality of package areas, each of which comprises a plurality of package units, and each of the package units comprising:
a die pad; and
a plurality of leads surrounding the die pad;
an insulation layer filled in gaps around each of the package units, wherein the thickness of the insulating layer is smaller than the thickness of the leads; and
a tape fixing the plurality of package areas.

2. The leadframe for a leadless package of claim 1, wherein the insulation layer is filled in gaps surrounding the die pad and the plurality of leads.

3. The leadframe for a leadless package of claim 1, wherein the insulation layer extends to the border of each of the package units.

4. The leadframe for a leadless package of claim 1, further comprising a plurality of side rails surrounding the plurality of the package units.

5. The leadframe for a leadless package of claim 4, wherein the insulation layer extends to the side rails.

6. The leadframe for a leadless package of claim 5, wherein the side rails further comprise a plurality of grooves in which the insulation layer is filled.

7. The leadframe for a leadless package of claim 6, wherein the depth of the grooves is smaller than the thickness of the side rails.

8. The leadframe for a leadless package of claim 1, wherein the insulation layer is made of epoxy resin.

9. The leadframe for a leadless package of claim 1, wherein the plurality of package units are arranged in a matrix.

10. The leadframe for a leadless package of claim 1, further comprising a plurality of connection portions connecting the plurality of package units.

11. A leadless package, comprising:
a die pad;
a plurality of leads surrounding the die pad;
an insulating layer filled in gaps surrounding the die pad and the plurality of leads, wherein the thickness of the insulating layer is smaller than the thickness of the leads; and
an encapsulation body overlaid on the die, the die pad, and the plurality of leads.

12. The leadless package of claim 11, wherein at least a surface of the die pad, and the plurality of leads is uncovered by the encapsulation body.

13. The leadless package of claim 11, wherein the insulation layer is made of epoxy resin.

14. The leadless package of claim 11, further comprising a plurality of metal wires electrically connecting the dies and the plurality of leads.

15. A leadframe for a leadless package, comprising:
a plurality of package areas, each of which comprises a plurality of package units, and each of the package units comprising:
a die pad; and
a plurality of leads surrounding the die pad; and
an insulation layer filled in gaps around each of the package units, wherein the thickness of the insulating layer is smaller than the thickness of the leads.
